(19) United States
(12) Patent Application Publication
(10) Pub. No.: US 2021/0234073 A1
(43) Pub. Date: Jul. 29, 2021

(54) DISPLAY DEVICE AND MANUFACTURING METHOD THEREFOR

(71) Applicant: SAMSUNG ELECTRONICS CO., LTD., Suwon-si (KR)

(72) Inventors: Dae Sik KIM, Suwon-si (KR); Sung Yeol KIM, Suwon-si (KR); Yasuhiro NISHIDA, Suwon-si (KR); Jong Hoon JUNG, Suwon-si (KR)

(73) Assignee: SAMSUNG ELECTRONICS CO., LTD., Suwon-si (KR)

(21) Appl. No.: 17/056,336

(22) PCT Filed: May 17, 2019
(86) PCT No.: PCT/KR2019/005925

§ 371 Date: Nov. 17, 2020

(30) Foreign Application Priority Data
May 24, 2018 (KR) 10-2018-0059194

(51) Int. Cl. H01L 33/50; G02F 1/1335

(52) U.S. Cl. CPC H01L 33/501; G02F 1/133524; G02F 1/133516

(57) ABSTRACT

According to an aspect disclosed, there is provided a display apparatus and a manufacturing method capable of maintaining color conversion efficiency and simultaneously expanding a color gamut by emitting light of two wavelengths to one light source. A display apparatus includes a light source configured to emit signal light having a first peak center wavelength and excitation light having a second peak center wavelength shorter than the first peak center wavelength; and a converter configured to convert color of the excitation light emitted by the light source. The light source may be configured to include at least one single chip in which a first semiconductor layer emitting the excitation light and a second semiconductor layer emitting the signal light are arranged in a horizontal or vertical direction.

### TECHNICAL FIELD

Embodiments of the disclosure relate to a display apparatus and a method of manufacturing the same including back light unit that emitting light.

### BACKGROUND ART

In general, a display apparatus is an output device that visually displays received or stored image information to a user, and is used in various home-based or business fields.

For example, the display apparatus is a monitor device connected to a personal computer or a server computer; portable computer devices such as navigation terminal devices, general television devices, Internet Protocol television (IPTV) devices, smartphones, tablet PCs, and personal digital assistants (PDAs); portable terminal devices such as a cellular phone; various display devices used to reproduce images such as advertisements and movies in industrial sites; or other various types of audio/video systems.

The display panel includes pixels arranged in a matrix form and a thin film transistor (TFT) provided in each of the pixels, and depending on the image signal applied to the thin film transistor, the amount of light passing through the pixels may change or the amount of light emitted from the pixels may change. The display apparatus may display an image by controlling an amount of light emitted from each of the pixels of the display panel.

In the display panel that displays an image, there are a self-luminous display panel that emits light by itself according to an image, and a non-luminescent display panel that blocks or passes light emitted from a separate light source according to the image.

The non-luminescent display panel is typically a liquid crystal display panel (LCD Panel). The liquid crystal display panel may include a backlight unit that emits light and a liquid crystal panel that blocks or passes light emitted from the backlight unit.

Here, the backlight unit emitting light may be classified into a three-chip light source element that emits red, green, and blue light, respectively, and a white light source element that converts monochromatic light into a desired wavelength. However, conventionally, such a backlight unit contains a trade-off problem between color conversion efficiency and color gamut expansion.

### DISCLOSURE

### Technical Problem

One aspect provides a display apparatus and a method of manufacturing the same for controlling method thereof capable of maintaining color conversion efficiency and simultaneously expanding a color gamut by emitting light of two wavelengths to one light source.

### Technical Solution

In accordance with an aspect of the disclosure, a display apparatus includes a light source configured to emit signal light having a first peak center wavelength and excitation light having a second peak center wavelength shorter than the first peak center wavelength; and a converter configured to convert color of the excitation light emitted by the light source.

The light source may be configured to include at least one single chip in which a first semiconductor layer emitting the excitation light and a second semiconductor layer emitting the signal light are arranged in a horizontal or vertical direction.

The first semiconductor layer may be configured to stack an N-type semiconductor and a P-type semiconductor sequentially, and emit the excitation light.

The second semiconductor layer may be configured to stack an N-type semiconductor and a P-type semiconductor sequentially on the first semiconductor layer, and emit blue light or green light as the signal light.

The first semiconductor layer and the second semiconductor layer may be combined with Indium Tin Oxide (ITO) junction.

The converter may be made of photoluminescence (PL) material that absorbs the excitation light and converts color.

The converter may be configured to include at least one or more first electrodes and second electrodes spaced apart from each other.

The first electrode may be formed to be connected to the P-type semiconductor on the first semiconductor, and the second electrode may be formed to be connected to the N-type semiconductor on the second semiconductor.

The light source may include a reflection layer provided under the first semiconductor layer and reflecting the excitation light and the signal light.

The display apparatus may further include an optical sheet configured to improve brightness of the signal light emitted from the light source.

The optical sheet may be configured to include a thin film element made of at least one of a dye and a pigment absorbing a preset wavelength band.

The display apparatus may further include a light guide plate configured to distribute uniformly the excitation light and the signal light emitted by the light source.

The light source may be provided on side of the light guide plate.

The display apparatus may further include alight diffusion sheet configured to diffuse light passing through the light guide plate.

The light source may be arranged on a light guide plate at predetermined intervals.

The converter may be configured to convert the excitation light into at least one of green light and red light.

In accordance with an aspect of disclosure, a method of manufacturing a display apparatus comprising a light source for emitting light and a converter for color conversion of excitation light emitted by the light source may include sequentially stacking a first semiconductor layer emitting the excitation light having a second peak center wavelength shorter than a first peak center wavelength and a second semiconductor layer emitting signal light having the first peak center wavelength; and ITO bonding the first semiconductor layer and the second semiconductor layer.

The first semiconductor layer may be configured to stack an N-type semiconductor and a P-type semiconductor sequentially, and the second semiconductor layer may be configured to stack an N-type semiconductor and a P-type semiconductor sequentially on the first semiconductor layer.

The method may further comprise etching one side of the N-type semiconductor included in the first semiconductor layer.

The etching may include etching the other side surface of the P-type semiconductor included in the first semiconductor layer and the P-type semiconductor of the second semiconductor layer, and the etching may further comprise plating the etched portion; and forming at least one first electrode and a second electrode that are spaced apart from each other.

In the display apparatus and manufacturing method according to the disclosed aspect, by emitting light of two wavelengths to one light source, it is possible to maintain color conversion efficiency and expand a gamut at the same time.

### DESCRIPTION OF DRAWINGS

FIG. 1 shows an appearance of a display apparatus according to an embodiment.

FIG. 2 is an exploded view of a display apparatus according to an exemplary embodiment.

FIG. 3A is a diagram for explaining a configuration of a backlight unit 200 according to an exemplary embodiment, and FIG. 3B is a diagram for explaining a configuration of a backlight unit according to another disclosed exemplary embodiment.

FIGS. 4A and 4B are diagrams for explaining an embodiment of the disclosed display apparatus 100.

FIGS. 5A and 5B are diagrams for a conventional white LED method, and FIG. 6 is a diagram for explaining a color gamut.

FIGS. 7A and 7B are diagrams for explaining an effect of a light source according to an exemplary embodiment, and FIG. 8 is a diagram for describing an effect of a light source according to another exemplary embodiment.

FIG. 9A to 9E are diagrams for explaining a method of manufacturing the disclosed light source.

FIGS. 10A and 10B are diagrams for explaining a light source in which electrodes are formed in the embodiment of FIG. 9A.

FIG. 11A to 11C are diagrams for explaining an electrode of a light source according to another disclosed embodiment.

FIGS. 12 to 14 are diagrams for describing various embodiments of the disclosed backlight unit.

### MODE FOR INVENTION

In the following description, like reference numerals refer to like elements throughout the specification. This specification does not describe all elements of the embodiments, and in the technical field to which the present invention pertains, there is no overlap between the general contents or the embodiments. Terms such as “unit,” “module,” “member,” and “block” may be embodied as hardware or software. According to embodiments, a plurality of “units,” “modules,” “members,” or “blocks” may be implemented as a single component or a single “unit,” “module,” “member,” or “block” may include a plurality of components.

In all specifications, it will be understood that when an element is referred to as being “connected” to another element, it can be directly or indirectly connected to the other element, wherein the indirect connection includes “connection via a wireless communication network.”

Also, when a part “includes” or “comprises” an element, unless there is a particular description contrary thereto, the part may further include other elements, not excluding the other elements.

Throughout the specification, when one member is positioned “on” another member, this includes not only the case where one member abuts another member, but also the case where another member exists between the two members.

The terms first, second, etc. are used to distinguish one component from another component, and the component is not limited by the terms described above.

An expression used in the singular form encompasses the expression of the plural form, unless it has a clearly different meaning in the context.

The reference numerals used in operations are used for descriptive convenience and are not intended to describe the order of operations and the operations may be performed in an order different unless otherwise stated.

Hereinafter, embodiments of the present disclosure will be described with reference to the accompanying drawings.

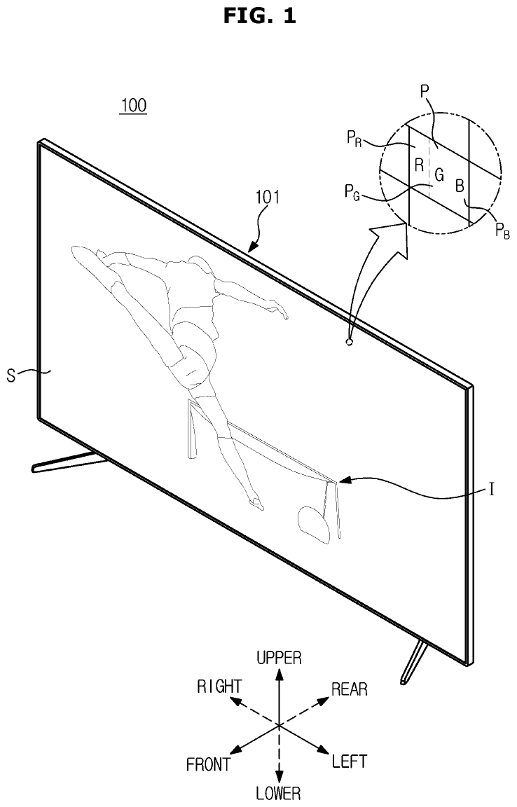

FIG. 1 shows an appearance of a display apparatus according to an embodiment.

A display apparatus 100 is a device capable of processing an image signal received from the outside and visually displaying the processed image. The display apparatus 100 is not limited by use, type, shape, and the like. For example, the display apparatus 100 may be implemented in various forms such as a television (TV), a monitor, a kiosk, a portable multimedia device, a portable communication device, and a portable computing device. If the display apparatus 100 is a device that visually displays an image, its form is not limited.

In addition, the display apparatus 100 may be a large display apparatus (Large Format Display, LFD) installed outdoors, such as on a roof of a building or at a bus stop. Here, the outdoors is not necessarily limited to the outdoors, and the display apparatus 100 according to an embodiment may be installed in a subway station, a shopping mall, a movie theater, a company, a shop, etc., wherever a large number of people can enter or exit.

The display apparatus 100 may receive a video signal and an audio signal from various content sources, and output video and audio corresponding to the video signal and the audio signal. For example, the display apparatus 100 may receive television broadcast content through a broadcast reception antenna or a wired cable, receive content from a content play back device, or receive content from a content providing server on a network.

Referring to FIG. 1, the display apparatus 100 may include a main body 101 accommodating a plurality of parts for displaying an image, and a screen S provided on one side of the main body 101 to display an image I.

The main body 101 forms the external shape of the display apparatus 100, and a component for the display apparatus 100 to display an image I may be provided inside the main body 101. The main body 101 shown in FIG. 1 has a flat plate shape, but the shape of the main body 101 is not limited to that shown in FIG. 1. For example, the main body 101 may be curved so that both ends of the main body 101 protrude forward and the center portion thereof is concave.

The screen S is formed on the front surface of the main body 101, and an image I as visual information may be displayed on the screen S. For example, a still image or a moving picture may be displayed on the screen S, and a 2D plane image or a 3D stereoscopic image may be displayed.

A plurality of pixels P are formed on the screen S, and the image I displayed on the screen S may be formed by a combination of light emitted from the plurality of pixels P. For example, one of the images I may be formed on the screen S by combining light emitted from the plurality of pixels P as a mosaic.

Each of the plurality of pixels P may emit light of various brightness and various colors.

In order to emit light of various brightness, each of the plurality of pixels P includes, for example, a configuration capable of directly emitting light (e.g., an organic light emitting diode) or light emitted by a backlight unit or the like (e.g., a liquid crystal panel) that can transmit or block.

In order to emit light of various colors, each of the plurality of pixels P may include sub-pixels P_{R}, P_{G}, and P_{B}.

The sub-pixels P_{R}, P_{G}, and P_{B} include the red sub-pixel P_{R} that can emit red light, the green sub-pixel P_{G} that can emit green light, and the blue sub-pixel P_{B} that can emit blue light. For example, the red sub-pixel P_{R} may emit red light having a wavelength of approximately 620 nm (nanometer, 1 billionth of a meter) to 750 nm, the green sub-pixel P_{G} can emit green light having a wavelength of approximately 495 nm to 570 nm, and the blue sub-pixel P_{B} may emit blue light having a wavelength of approximately 450 nm to 495 nm.

By the combination of the red light of the red sub-pixel P_{R}, the green light of the green sub-pixel P_{G} and the blue light of the blue sub-pixel P_{B}, each of the plurality of pixels P may emit light of various brightness and various colors.

The screen S shown in FIG. 1 is a flat plate shape, but the shape of the screen S is not limited to that shown in FIG. 1. For example, depending on the shape of the cabinet 101, the screen S may have a shape in which both right and left ends protrude forward and the center portion is concave.

The display apparatus 100 may include various types of display panels for displaying an image. For example, the display apparatus 100 may include a self-luminous display that displays an image using a device that emits light by itself. The self-luminous display includes a light emitting diode module (LED module) or an organic light emitting diode panel (OLED panel).

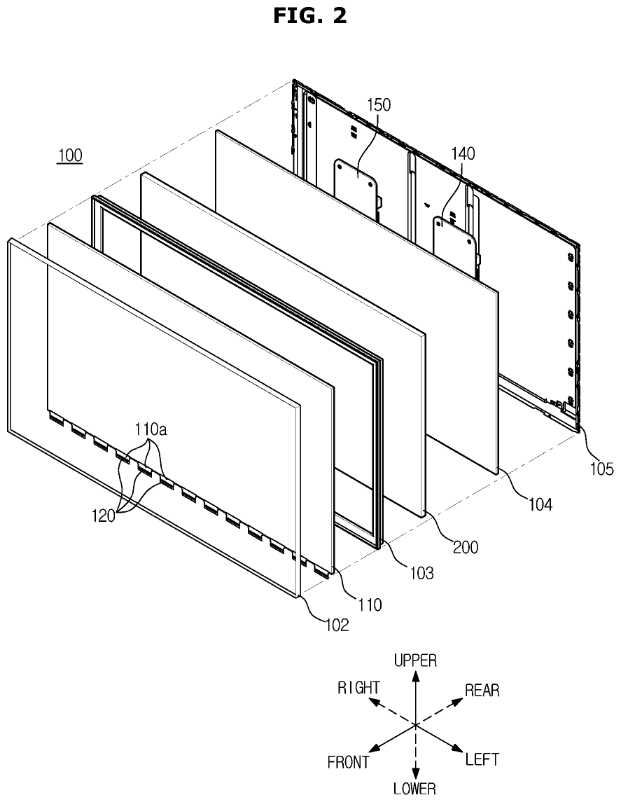

FIG. 2 is an exploded view of a display apparatus according to an exemplary embodiment.

Referring to FIG. 2, various component parts for generating an image I on the screen S may be provided inside the main body 101.

In the main body 101, a backlight unit 200 for emitting surface light to the front, a liquid crystal panel 110 that blocks or passes light emitted from the backlight unit 200, a control assembly 140 for controlling the operation of the backlight unit 200 and the liquid crystal panel 110, a power assembly 150 that supplies power to the backlight unit 200 and the liquid crystal panel 110 are provided. In addition, the main body 101, a bezel 102 for supporting and fixing the liquid crystal panel 110, the backlight unit 200, the control assembly 140, and the power assembly 150, and a frame middle mold 103, a bottom chassis 104, and a r rear cover 105 are further provided.

The backlight unit 200 may include a point light source that emits white light, and may refract, reflect, and scatter light to convert light emitted from the point light source into uniform surface light. Here, the point light source included in the backlight unit 200 emits short wavelength, 350 nm to 440 nm blue light as excitation light, and long wavelength, 440 nm to 470 nm blue light as signal light. In addition, the point light source according to another embodiment emits short wavelength as excitation light, blue light of 350 nm to 440 nm, and blue light of long wavelength as signal light and green light of 530 nm to 570 nm. A detailed description of the backlight unit 200 will be described later through other drawings below.

The liquid crystal panel 110 is provided in front of the backlight unit 200 and blocks or passes light emitted from the backlight unit 200 to form an image I.

The front surface of the liquid crystal panel 110 forms the screen S described above, and may include a plurality of pixels P. The plurality of pixels P included in the liquid crystal panel 110 may each independently block or pass light from the backlight unit 200, and light passed by the plurality of pixels P may form an image I displayed on the screen S.

The liquid crystal panel 110 may include at least one of a polarizing film, a transparent substrate, a pixel electrode, a thin film transistor (TFT), a liquid crystal layer, a common electrode, and a color filter.

The transparent substrate may be made of tempered glass or transparent resin, and fixes a pixel electrode, a thin film transistor, a liquid crystal layer, a common electrode, and a color filter. Each of the polarizing films can pass specific light and block other light. The color filter may include a red filter for passing red light, a green filter for passing green light, and a blue filter for passing blue light. The area formed by the color filter corresponds to the above-described pixel P.

The thin film transistor may pass or block a current flowing through the pixel electrode, and an electric field may be formed or removed between the pixel electrode and the common electrode according to the turn-on (closed) or turn-off (open) of the thin film transistor. The thin film transistor may be made of poly-silicon, and may be formed by semiconductor processes such as lithography, deposition, and ion implantation processes.

The pixel electrode and the common electrode are formed of a metal material through which electricity is conducted, and may generate an electric field for changing the arrangement of liquid crystal molecules constituting the liquid crystal layer. The pixel electrode and the common electrode are made of a transparent material and can pass light incident from the outside. For example, the pixel electrode and the common electrode may be composed of Indium Tin Oxide (ITO), Indium Zinc Oxide (IZO), Ag nano wire, and carbon nano tube (CNT), graphene or PEDOT (3,4-ethylenedioxythiophene).

A liquid crystal layer is formed between the pixel electrode and the common electrode, and the liquid crystal layer is filled by liquid crystal molecules.

Liquid crystals represent an intermediate state between a solid (crystal) and a liquid. In general, when heat is applied to a solid substance, a state change occurs from a solid state to a transparent liquid state at a melting temperature. In contrast, when heat is applied to a liquid crystal material in a solid state, the liquid crystal material changes to an opaque and turbid liquid at a melting temperature and then changes to a transparent liquid state. Most of these liquid crystal materials are organic compounds, and the molecular shape is in the shape of a long and thin rod, and the arrangement of molecules is like an irregular state in one direction, but may have a regular crystal shape in other directions. As a result, the liquid crystal has both the fluidity of the liquid and the optical anisotropy of the crystal (solid).

In addition, liquid crystals may exhibit optical properties according to changes in electric field. For example, in a liquid crystal, the orientation of the molecular arrangement constituting the liquid crystal may change according to the change of the electric field.

When an electric field is generated in the liquid crystal layer, the liquid crystal molecules in the liquid crystal layer are arranged according to the direction of the electric field. When the electric field is not generated in the liquid crystal layer, the liquid crystal molecules may be irregularly disposed or may be disposed along the alignment layer.

As a result, the optical properties of the liquid crystal layer may vary depending on the presence or absence of an electric field passing through the liquid crystal layer, for example, the disclosed liquid crystal panel may include all of a TN (Twisted Nematic) liquid crystal panel, a vertical alignment (VA) liquid crystal panel, and an IPS (In-Plane-Switching) liquid crystal panel.

Referring back to FIG. 2, the liquid crystal panel 110A includes a cable 110a for transmitting image data to the liquid crystal panel 110, and a Display Driver Integrated Circuit (DDI) (hereinafter referred to as a ‘driver IC’) for processing digital image data and outputting an analog image signal.

The driver IC 120 may receive image data and power from the control assembly 140/power assembly 150, and transmit the image data and driving current to the liquid crystal panel 110.

The control assembly 140 may include a control circuit that controls the operation of the liquid crystal panel 110 and the backlight unit 200. The control circuit may process image data received from an external content source, transmit image data to the liquid crystal panel 110, and transmit dimming data to the backlight unit 200.

The control assembly 140 may include a control circuit that controls the operation of the liquid crystal panel 110 and the backlight unit 200. The control circuit may process image data received from an external content source, transmit image data to the liquid crystal panel 110, and transmit dimming data to the backlight unit 200.

The power assembly 150 may supply power to the liquid crystal panel 110 and the backlight unit 200 so that the backlight unit 200 outputs surface light and the liquid crystal panel 110 blocks or passes the light of the backlight unit 200.

The control assembly 140 and the power assembly 150 may be implemented with a printed circuit board and various circuits mounted on the printed circuit board. For example, the power circuit may include a capacitor, a coil, a resistance element, a processor, and the like, and a power circuit board on which the same. Further, the control circuit may include a memory, a processor, and a control circuit board on which they are mounted.

Meanwhile, the disclosed display apparatus 100 may include various examples in addition to the liquid crystal panel 110 described above. That is, the disclosed display apparatus 100 suffices to include the backlight unit 200 described below.

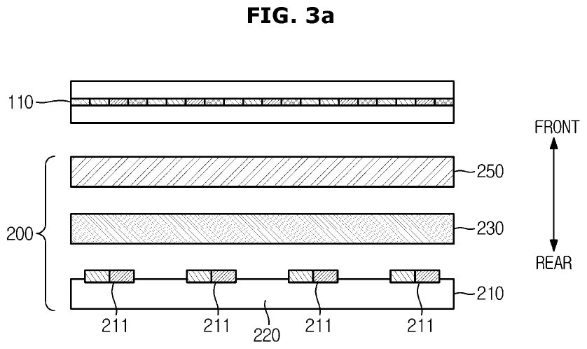

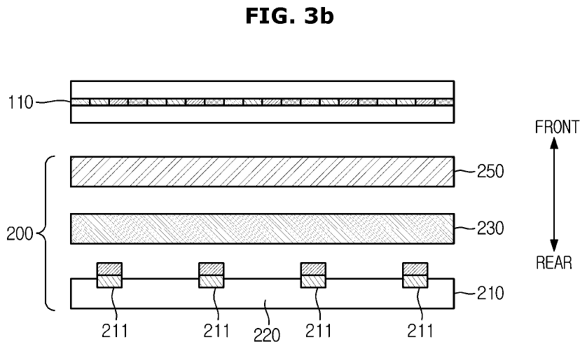

FIG. 3A is a diagram for explaining a configuration of a backlight unit 200 according to an exemplary embodiment, and FIG. 3B is a diagram for explaining a configuration of a backlight unit according to another disclosed exemplary embodiment. It will be described together below to avoid redundant description.

In the disclosed display apparatus 100, a backlight unit 200 is provided behind the liquid crystal panel 110 described above. The backlight unit 200 includes a light source unit 210 emitting light from the rear, a converter 230 for converting the color of the excitation light emitted from the light source 210, and an optical sheet (Enhancer) 250 that improves the brightness of white light emitted through the converter 230.

Specifically, the light source 210 may be provided in a form in which a plurality of light sources 211 for emitting light of two wavelengths are inserted into a light guide plate 220. The plurality of light sources 211 may be disposed at equal intervals to have uniform brightness.

The light source 211 of FIGS. 3A and 3B shows a direct-type back light unit uniformly spread and disposed from the center of the light guide plate 220 to the side. However, the disclosed backlight unit 200 is not necessarily limited to a direct type backlight unit, the light source 211 may also be applied to an edge-type back light unit positioned on the side of the light guide plate 220.

The light source 211 provided as a single chip emits signal light having a first peak center wavelength and excitation light having a second peak center wavelength shorter than the first peak center wavelength to the converter 230.

Here, the peak center wavelength may vary according to a preset light emitted from the light source 211, and for example, the signal light having the first peak center wavelength may be blue light having a peak center wavelength of 460 nm. Further, the excitation light having a second peak center wavelength shorter than the first peak center wavelength may be blue light having a peak center wavelength of 440 nm or green light having a peak center wavelength of 530 nm according to an embodiment.

That is, the disclosed light source 211 emits light having two different wavelengths from one chip, thereby simultaneously satisfying color gamut expansion and color conversion efficiency. Effects and manufacturing methods of the disclosed light source 211 will be described later with reference to other drawings below.

Meanwhile, referring to FIG. 3A, the light source 211 may be provided in a form in which a first semiconductor layer emitting light of a first wavelength and a second semiconductor layer emitting light of a second wavelength are arranged in a horizontal direction on the light guide plate 220. Here, the horizontal direction is a direction other than the front and the rear, and includes the right, left, upper and lower sides described above in FIG. 2.

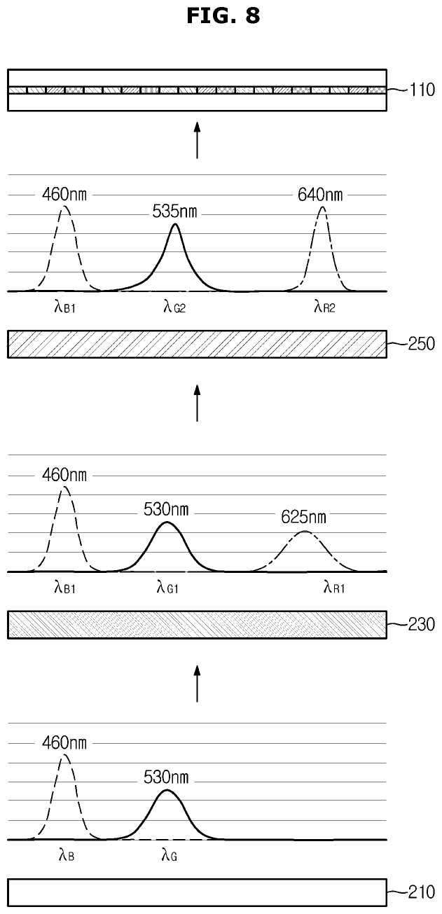

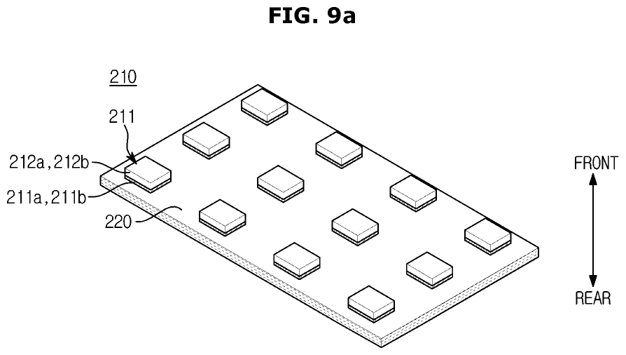

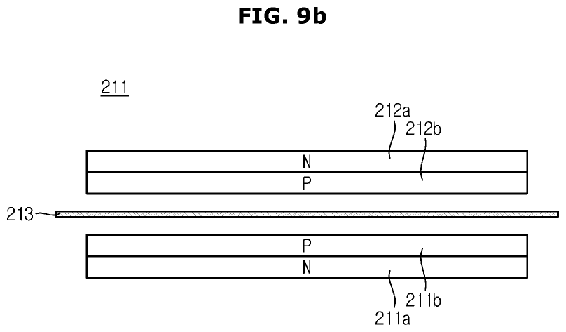

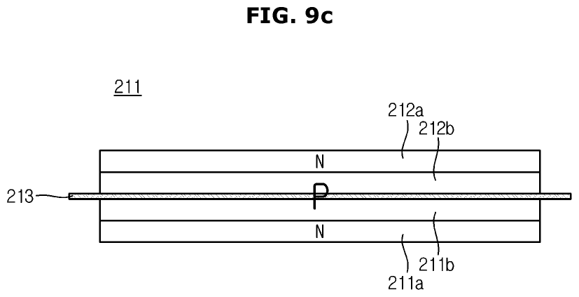

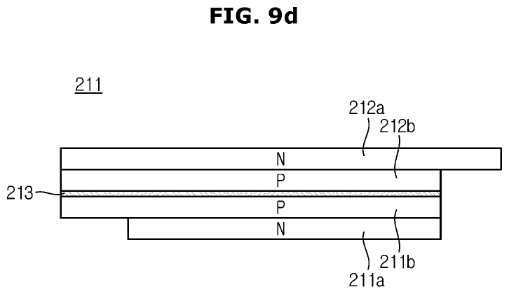

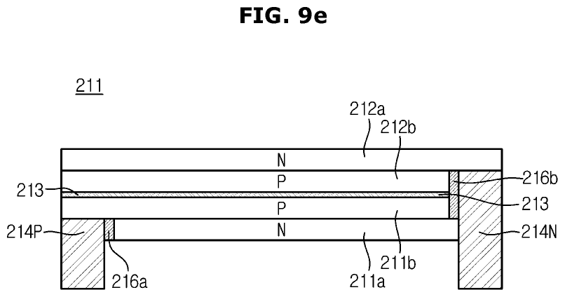

Referring to FIG. 3B, the light source 211 according to another disclosed embodiment may be provided in a form of a first semiconductor layer emitting light of a first wavelength and a second semiconductor layer emitting light of a second wavelength are stacked in a vertical direction. Here, the vertical direction refers to a direction from the light guide plate 210 toward the converter 230 and means a front side. A detailed description including the first semiconductor layer and the second semiconductor layer will be described later in detail with reference to the drawings in FIG. 9A.

The converter 230 is provided with a phosphor or a quantum dot (QD), and absorbs excitation light among two types of light emitted by the light source 211 to convert color. According to an embodiment, when the light source 211 emits blue light having a peak central wavelength of 440 nm as excitation light, the converter 230 converts the emitted blue light into green light having a peak center wavelength of 535 nm and red light having a peak center wavelength of 640 nm. In another embodiment, when the light source 211 emits blue light having a peak center wavelength of 460 nm and green light having a peak center wavelength of 530 nm, the converter 230 can convert red light having a peak center wavelength of 625 nm.

It is sufficient if the converter 230 is made of PL (Photoluminescence) material capable of color conversion.

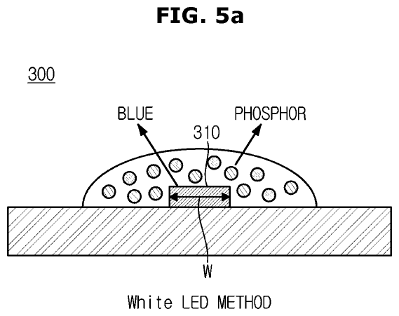

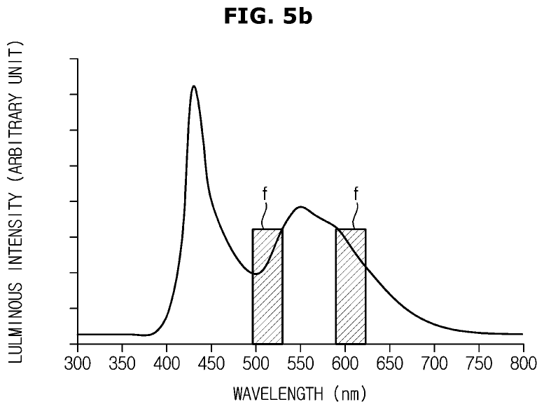

The optical sheet 250 includes a thin film element made of at least one of a dye and a pigment that absorbs a predetermined wavelength band, and the half width of the absorbed light may be reduced. Accordingly, light transmitted to the liquid crystal panel 110 through the optical sheet 250 may enlarge a color gamut. A detailed description related to gamut expansion will be described later in FIG. 5.

Meanwhile, in addition to the thin film element, the optical sheet 250 may further include a sheet that improves luminance of various lights or improves uniformity of luminance.

For example, the optical sheet 250 may include at least one of a diffusion sheet, a prism sheet, and a reflective polarizing sheet. When the light is emitted at an angle from the diffusion sheet, the prism sheet refracts the emitted light again to focus light. In addition, the reflective polarizing sheet may pass light polarized in the same direction as a predetermined polarization direction, or may reflect light polarized in a direction different from the polarization direction.

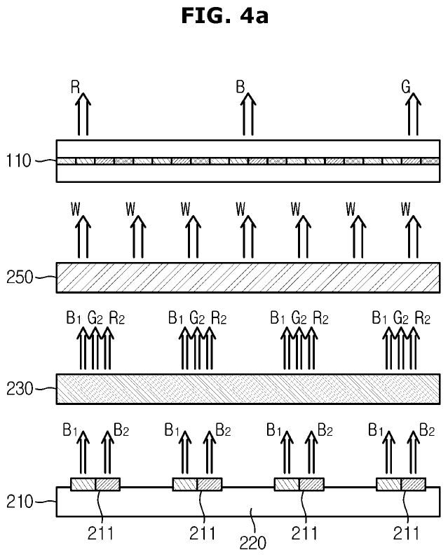

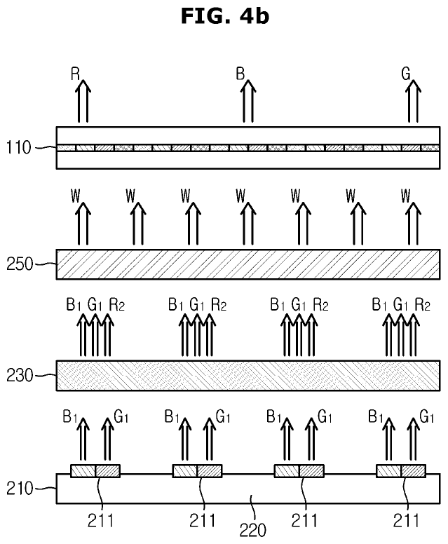

FIGS. 4A and 4B are diagrams for explaining an embodiment of the disclosed display apparatus 100.

As described above, each of the plurality of light sources 211 provided in the light guide plate 220 emits signal light having a long peak center wavelength and excitation light having a short peak center wavelength. Hereinafter, a description will be given centering on the embodiment of FIG. 3A, but is not limited thereto, and the embodiment of FIG. 3B is equally applied.

Referring to FIG. 4A, the light source 211 emits blue light B1 having a first peak center wavelength and blue light B2 having a second peak center wavelength. Here, the first peak center wavelength has a relatively longer wavelength than the second peak center wavelength. For example, the light source 211 may emit blue light B1 having a peak central wavelength of 460 nm and blue light B2 having a peak central wavelength of 410 nm.

The emitted blue light B2 having the second peak center wavelength is color converted in converter 230. Here, the shorter the wavelength, the higher the color conversion efficiency. That is, the converter 230 is used as excitation light that converts the blue light B2 having the second peak center wavelength into green light and red light. For example, the converter 230 emits green light (G2) having a peak center wavelength of 530 nm and red light (R2) having a peak center wavelength of 630 nm to the optical sheet 250

Finally, the optical sheet 250 transmits blue light B1 with a relatively long peak center wavelength and the white light in which the green light G2 and the red light R2 converted by the converter 230 to the liquid crystal panel 110.

Meanwhile, the above-described peak center wavelength is only an example, and is not necessarily limited to the example values. That is, the first peak center wavelength may be included in 440 nm to 470 nm, and it is sufficient if the second peak center wavelength is included between 350 nm and 440 nm.

Referring to FIG. 4B, the light source 211 according to another disclosed embodiment may emit blue light B1 having a first peak center wavelength of 460 nm and green light G1 having a second peak center wavelength of 535 nm.

The converter 230 converts blue light (G1) having a first peak center wavelength into excitation light into red light (R2) having a peak center wavelength of 625 nm. Blue light B1, green light G1 and red light R2 emitted from the converter 230 are transmitted to the optical sheet 250, and after the shift of the peak center wavelength of red light occurs, in the optical sheet 250, white light in which blue light having a peak center wavelength of 460 nm, green light having a peak center wavelength of 530 nm, and red light having a peak center wavelength of 640 nm is combined is emitted to the liquid crystal panel 110.

According to this embodiment, since the light source 211 can preset the peak center wavelength of the emitted green light G1 and the blue light B1, in addition to the increase in the color conversion efficiency mentioned in FIG. 4A, it may be advantageous to extend the gamut. A detailed description of the effects of the disclosed light source 211 will be described later with reference to the following drawings.

FIGS. 5A and 5B are diagrams for a conventional white LED method, and FIG. 6 is a diagram for explaining a color gamut.

First, referring to FIG. 5A, a conventional white LED (LIGHT EMITTING DEVICE) light source 300 includes a yellow phosphor 320 capable of color conversion above a blue monochromatic light source 310. That is, the white LED light source 300 excites blue light emitted by the monochromatic light source 310 as green light and red light by the phosphor 320.

This method has the advantage of being easier to control each LED than the method of separately implementing three light sources of blue, green and red before.

Meanwhile, in the conventional white LED method, the area (W) of the monochromatic light source 310 is increased or a high current is injected into the monochromatic light source 310 in order to increase color conversion efficiency. However, this measure has a problem of causing a droop phenomenon (a rapid decrease in efficiency when the power consumption is higher than the threshold current) due to power consumption or injection current density.

Referring to FIG. 5B, in the conventional white LED method, color conversion is performed by filtering a predetermined band of the wavelength band of blue light emitted by the monochromatic light source 310. That is, since a part of the energy of the blue wavelength band emitted by the monochromatic light source 310 is used for color conversion, the color conversion efficiency increases as the energy is a shorter peak center wavelength.

However, the conventional white LED method is disadvantageous in color gamut expansion when the peak center wavelength of the monochromatic light source 310 is adjusted to increase color conversion efficiency.

Here, color gamut refers to a color gamut created for an arbitrary purpose, and refers to a subset of colors in color reproduction. When the display device is limited in a given color space or output to accurately represent colors, this becomes a gamut.

Referring to FIG. 6, the gamut may be expressed as a triangular area in the xy chromaticity diagram of the XYZ color system determined by the Commission Internationale de l'Eclairage (CIE). That is, the gamut may be determined according to the position of the vertex of the triangle, and the peak center wavelength of red, blue, and green corresponding to the signal light determines the position of the vertex of the triangle.

If the peak center wavelength of the conventional monochromatic light source 310 is shortly adjusted in order to increase the color conversion efficiency, the peak center wavelengths of the other two colors after the color conversion are shortened together, so that the gamut (a triangle with a small area) is reduced.

Therefore, in order to expand the gamut, the conventional white LED method needs to change one or more peak center wavelengths.

In order to change the peak center wavelength, the conventional white LED method may adjust the monochromatic light source 310 or adjust the characteristics of the phosphor. However, when the blue light of the monochromatic light source 310 is adjusted, a problem may occur in light conversion efficiency as described above.

In addition, another method for controlling the characteristics of the phosphor has a problem in that it is difficult to produce a half-width smaller than the currently manufactured QD.

Specifically, the gamut is determined by the half width in addition to the above-described peak center wavelength. That is, if the half value width is small, the color purity of the spectral distribution map is increased and the color gamut is enlarged.

Green QD, which is currently the highest level, has a half width of 40 nm, making it difficult to expand the color gamut further, and in the case of an optical filter having a narrower band than a dye-type absorption color filter. In the conventional white LED method, a new necessity for expanding the color gamut is raised.

The disclosed display apparatus 100 emits a signal light having a long first peak center wavelength in one light source 211 for gamut expansion, and simultaneously converts color by emitting excitation light having a second peak center wavelength having a short peak center wavelength in order to prevent color efficiency loss.

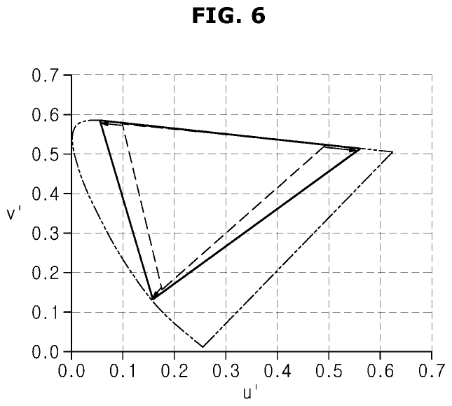

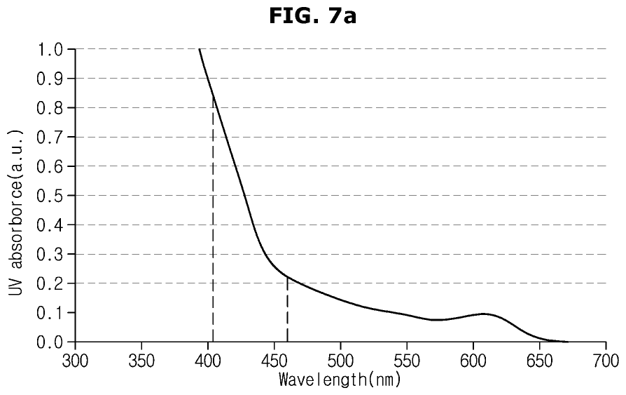

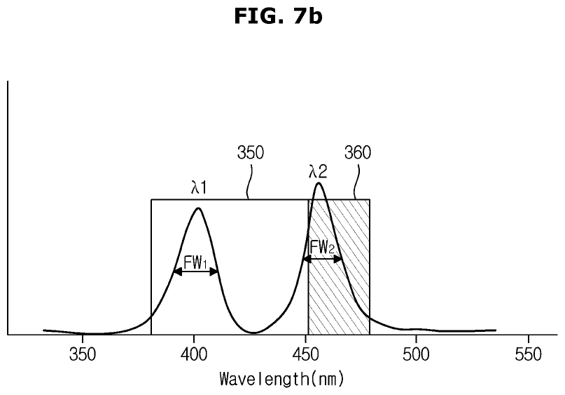

FIGS. 7A and 7B are diagrams for explaining an effect of a light source according to an exemplary embodiment, and FIG. 8 is a diagram for describing an effect of a light source according to another exemplary embodiment.

As described above, the light source 211 according to the disclosed embodiment may emit blue light having a peak center wavelength of 460 nm as a signal light and blue light having a peak center wavelength of 410 nm as excitation light.

Referring to FIG. 7A, the X-axis represents the peak center wavelength, and the Y-axis represents the absorption efficiency of light. In addition, the peak center wavelength of 410 nm is more than three times the light absorption rate compared to the peak center wavelength of 460 nm.

When the conventional white LED type light source 310 outputs only one of blue light having a peak center wavelength of 410 nm or 460 nm, the absorption efficiency of light (color conversion efficiency) and color gamut expansion cannot be achieved at the same time. However, by emitting blue light with a peak center wavelength of 460 nm as signal light and using blue light with a peak center wavelength of 410 nm as excitation light, the disclosed light source 211 can achieve a light absorption rate of 3 times or more compared to the conventional monochromatic light source 310 using blue light having a peak center wavelength of 460 nm.

Referring to FIG. 7B, a wavelength band 350 of blue light having a peak center wavelength of 410 nm is wider than a wavelength band 360 of blue light having a peak center wavelength of 460 nm. Further, the half-value width (FW2) of the wavelength band 360 of blue light having a peak center wavelength of 460 nm is narrower than the half-value width (FW1) of the wavelength band 350 of blue light having a peak center wavelength of 410 nm.

Accordingly, the disclosed display apparatus 100 uses blue light in a wide wavelength band 350 as excitation light, thereby increasing light efficiency, and at the same time using a small half width 361 as signal light, which is advantageous in broadening the gamut compared to the prior art.

Referring to FIG. 8, the disclosed light source 211 may emit blue light having a peak center wavelength of 460 nm as excitation light, and may emit green light having a peak center wavelength of 530 nm as signal light.

Unlike the above-described embodiments in FIGS. 7A and 7B, the light source 211 that outputs green light having a peak center wavelength of 530 nm uses green light as a signal light, and is thus advantageous in broadening the gamut compared to the prior art.

When green light is emitted as signal light, the converter 230 converts blue light with a long wavelength of 460 nm into red light with a peak center wavelength of 625 nm. In FIG. 7A and the like, a portion that is insufficient in terms of gamut expansion compared to the above-described embodiment enables gamut expansion by shifting the optical sheet 250 from a peak center wavelength of 625 nm to red light having a peak center wavelength of 640 nm.

In addition, in the embodiment of FIG. 8, the display apparatus 100 outputs green light of a long wavelength which is advantageous for color gamut expansion without having to examine color conversion efficiency. Eventually, the display apparatus 100 finally enters the liquid crystal panel 110 with blue light having a peak center wavelength of 460 nm, green light having a peak center wavelength of 530 nm, and red light having a peak center wavelength of 640 nm, thereby having an advantageous effect on color gamut expansion. Have.

FIG. 9A to 9E are diagrams for explaining a method of manufacturing the disclosed light source.

Specifically, FIGS. 9A to 9E illustrate a method of manufacturing a single chip in which a semiconductor layer of a light source is arranged in a vertical direction toward the front. It will be described together below to avoid redundant description.

Referring first to FIG. 9A, a light source 211 according to the disclosed embodiment emits light having two different peak center wavelengths on one chip. For this purpose, the disclosed light source 211 stacks a first semiconductor layers 211a and 211b emitting excitation light having a first peak center wavelength and a second semiconductor layers 212b and 212a emitting signal light having a second peak center wavelength.

The general light emitting element uses the principle of recombination of electrons and holes. In the disclosed light source 211, an N-type semiconductor and a P-type semiconductor are sequentially stacked for this purpose. That is, the first semiconductor layers 211a and 211b emit excitation light having a second peak center wavelength shorter than the first peak center wavelength due to the recombination principle of electrons and holes. Further, the second semiconductor layers 212b and 212a also emit signal light having a first peak center wavelength by the recombination principle of electrons and holes.

Referring to FIG. 9b and FIG. 9c, the disclosed light source 211 emits first semiconductor layers 211a and 211b in which an N-type semiconductor and a P-type semiconductor are stacked and a signal light. The second semiconductor layers 212b and 212a in which the N-type semiconductor and the P-type semiconductor are stacked are sequentially stacked by ITO (Indium Tin Oxide) bonding. Consequently, the bonded light source 211 is provided in a structure in which an N-type semiconductor-P-type semiconductor-N-type semiconductor is stacked.

After ITO bonding, the disclosed light source 211 is electrode etched, as shown in FIG. 9C. That is, in the disclosed light source 211, a portion of the N-type semiconductor 211a of the first semiconductor layer provided below is etched, and in particular, the N-type semiconductor 212a of the second semiconductor layer provided thereon is etched to be exposed.

The light source 211 disclosed later is plated to form an electrode, as shown in FIG. 9E. Specifically, the etching surface 216a of the N-type semiconductor 211a of the first semiconductor layer is plated, the etching surface 216b of the P-type semiconductor 211b of the first semiconductor layer and the P-type semiconductor 212b of the second semiconductor layer are plated.

After plating, electrodes 214P and 214N are formed on the disclosed light source 211. Specifically, the first electrode 214P is electrically connected to the P-type semiconductor 212b of the first semiconductor layer, the second electrode 214N is electrically connected to the N-type semiconductor 211a of the first semiconductor layer and the N-type semiconductor 212a of the second semiconductor layer.

One disclosed light source 211 is connected to the power supply assembly 150 through a common electrode (P electrode, N electrode), is supplied with power, and emits light having two different peak center wavelengths.

Meanwhile, a sapphire or silicon wafer used in a manufacturing process of a light emitting element emitting blue light and green light has similar electrical characteristics. For example, the light emitting element emitting green light can be easily manufactured by adding a simple manufacturing process in which impurities such as indium are injected in the manufacturing process of the light emitting element emitting blue light. On the other hand, the manufacturing process of the light emitting element emitting red light is different from that of manufacturing the light emitting element emitting blue light.

Therefore, since the light emitting element of blue light and the light emitting element of green light that are manufactured by almost the same process have high linearity, the disclosed light source 211 can be easily manufactured through wafer bonding technology.

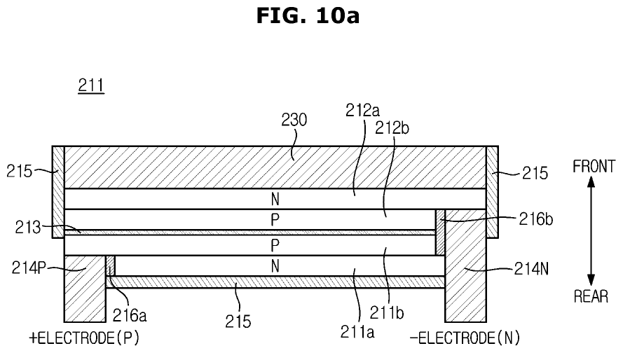

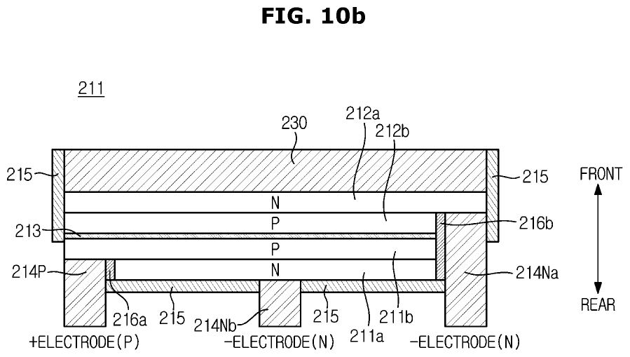

FIGS. 10A and 10B are diagrams for explaining a light source in which electrodes are formed in the embodiment of FIG. 9A. It will be described together below to avoid redundant description.

Referring to FIG. 10A, the disclosed light source 210 and converter 230 may be provided in order toward the front. The second semiconductor layers 212a and 212b and the first semiconductor layers 211a and 211b may be provided behind the converter 230, and a reflective layer 215 may be provided.

Here, the reflective layer 215 prevents signal light and excitation light emitted from the first semiconductor layers 211a and 211b and the second semiconductor layers 212a and 212b from traveling backward and reflects it forward. Meanwhile, the reflective layer 215 may be provided on the side of the light source 210 and the converter 230 as well.

As illustrated in FIG. 10A, in the light source 210, the P-type semiconductor 211b of the first semiconductor layer and the P-type semiconductor 212b of the second semiconductor layer are electrically connected to the first electrode 214P on one side thereof. In addition, the N-type semiconductor 211a of the first semiconductor layer and the N-type semiconductor 212a of the second semiconductor layer are electrically connected to the second electrode 214N.

In this embodiment, the first semiconductor layers 211a and 211b and the second semiconductor layers 212a and 212b connect the first electrode 214P and the second electrode 214N having the same potential in common.

Referring to FIG. 10B, the light source 210 and the converter 230 may also be provided in order toward the front. That is, the second semiconductor layers 212a and 212b and the first semiconductor layers 211a and 211b are provided behind the converter 230, and the reflective layer 215 may be provided.

Unlike FIG. 10A, in the light source 210, one side of the N-type semiconductor 211a of the first semiconductor layer is plated, and is not electrically connected to the first electrode 214Na. In addition, the reflective plate 215 provided below is etched, so that the third electrode 214Nb is electrically connected to the N-type semiconductor 211a of the first semiconductor layer.

In this embodiment, the second electrodes 214P are connected in common, but the first semiconductor layers 211a and 211b and the second semiconductor layers 212a and 212b are connected to different N electrodes, respectively.

Meanwhile, in addition to those described with reference to FIGS. 10A and 10B, the disclosed light source 210 may include electrodes in various forms, and is not limited thereto.

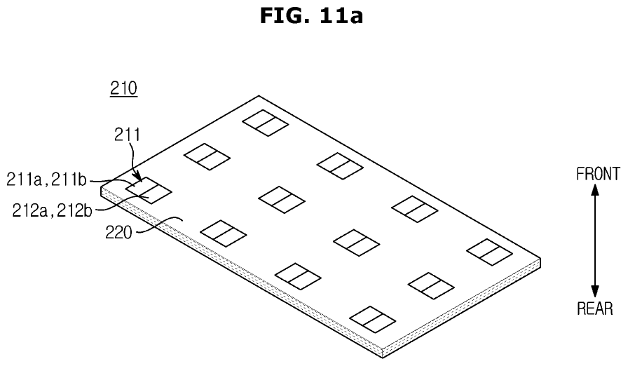

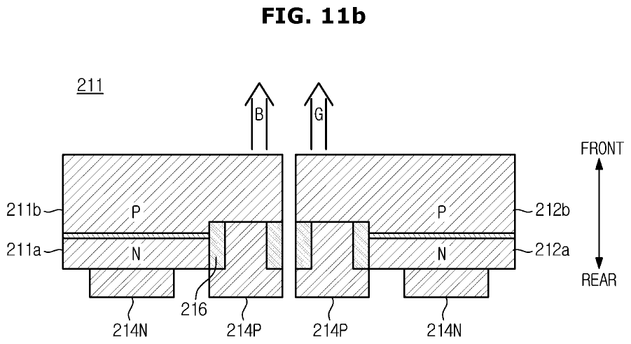

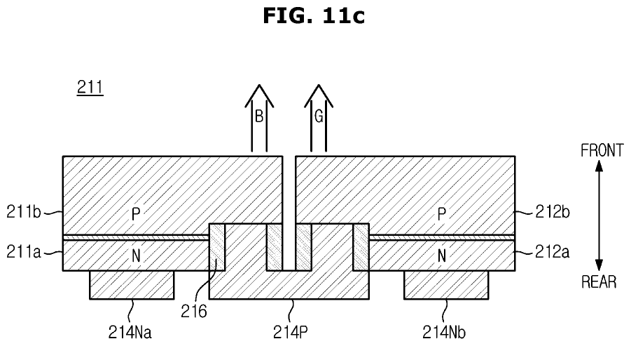

FIG. 11A to 11C are diagrams for explaining an electrode of a light source according to another disclosed embodiment.

Referring to FIG. 11A, the light source 211 may be manufactured as a single chip by horizontally arranging the first semiconductor layers 211a and 211b and the second semiconductor layers 212a and 212b parallel to the converter 230. Here, the first semiconductor layers 211a and 211b emit excitation light having a shorter peak center wavelength than the signal light emitted by the second semiconductor layers 212a and 212b.

Referring to FIG. 11B, in the light source 211 included as a single chip in another disclosed embodiment, the N-type semiconductor 211a of the first semiconductor layer and the second electrode 214N are electrically connected. In addition, the P-type semiconductor 211b of the first semiconductor layer is electrically connected to the first electrode 214P, and the first electrode 214P is insulated from the N-type semiconductor 211a of the first semiconductor layer by plating 216.

The N-type semiconductor 212a of the second semiconductor layer arranged horizontally with the first semiconductor layer is electrically connected to the second electrode 214N. In addition, the P-type semiconductor 212b of the second semiconductor layer is electrically connected to the first electrode 214P, and the first electrode 214P is insulated from the N-type semiconductor 211a of the first semiconductor layer by plating 216.

This embodiment corresponds to the circuit connection of FIG. 10A.

Referring to FIG. 11C, in the light source 211 included as a single chip, the N-type semiconductor 211a of the first semiconductor layer and the second electrode 214Na are electrically connected. In addition, the N-type semiconductor 212a of the second semiconductor layer and the second electrode 214Nb are electrically connected, respectively.

Unlike FIG. 11B, In the light source 211 according to the disclosed embodiment, the P-type semiconductor 211b of the first semiconductor layer and the P-type semiconductor 212b of the second semiconductor layer may be connected to the second electrode 214P of the same potential.

This embodiment corresponds to the circuit connection of FIG. 10B.

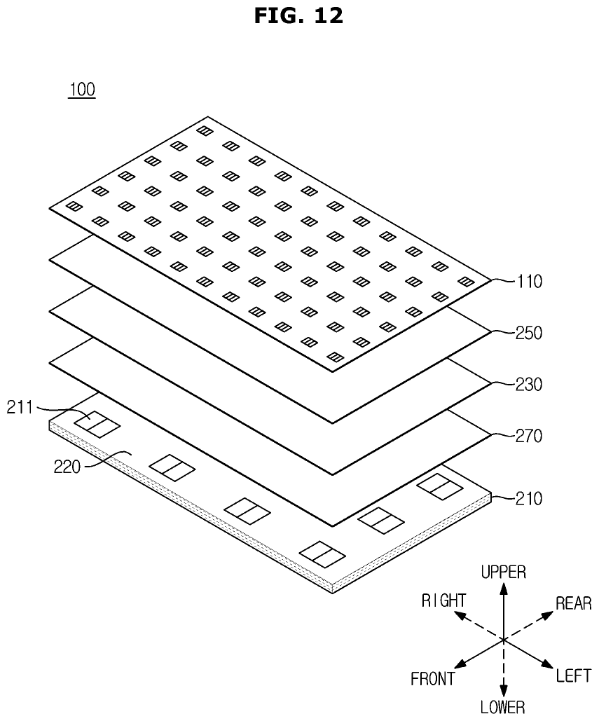

FIGS. 12 to 14 are diagrams for describing various embodiments of the disclosed backlight unit.

The disclosed light source 210 outputs light having different peak center wavelengths from one light source 211. The backlight unit 200 is divided into a direct type backlight unit and an edge type backlight unit according to a position where the light source 211 is disposed.

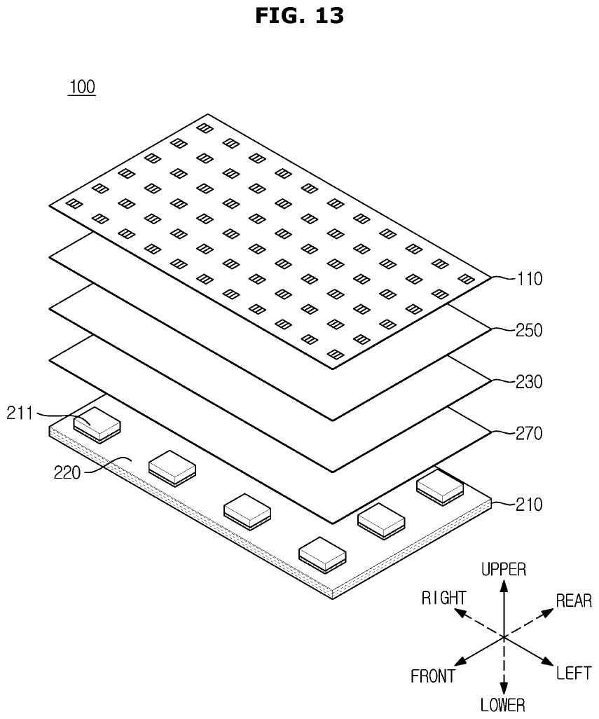

First, referring to FIGS. 12 and 13, the backlight unit 220 according to an embodiment is a direct type, and the disclosed light source 211 is uniformly disposed on the light guide plate 220.

In the case of FIG. 12, in the light guide plate 220 of the disclosed backlight unit 220, the light source 211 may be configured as a single chip by arranging the first semiconductor layer and the second semiconductor layer in a horizontal direction parallel to the converter 230. In comparison with this, in the case of FIG. 13, the light guide plate 220 of the disclosed backlight unit 220, the light source 211 may be configured as a single chip by stacking the first semiconductor layer and the second semiconductor layer in a direction perpendicular to the converter 230.

However, all of these embodiments can be applied to a direct type backlight unit.

Meanwhile, a light diffusion sheet (Diffuser) 270 for diffusing light may be additionally provided between the converter 230 and the light source 210 in the embodiments of FIGS. 12 and 13. Since the plurality of light sources 211 disposed in the light source 210 are point light sources, it may be difficult for the light guide plate 220 to diffuse light toward the front. Therefore, the direct type backlight unit 200 may further include a light diffusion sheet 270.

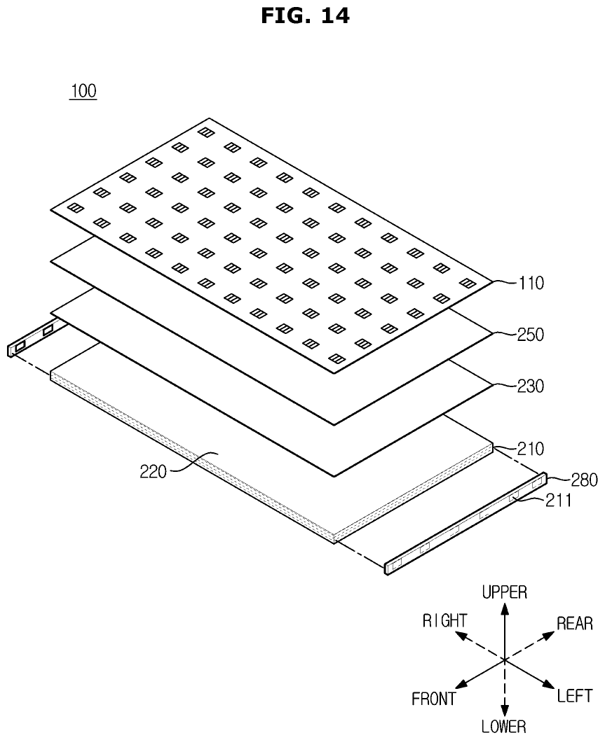

Referring to FIG. 14, a backlight unit 220 according to another exemplary embodiment has an edge type, and a light source 211 is positioned on a side surface of the light guide plate 220. Light incident on the light guide plate 220 may move from the side of the light guide plate 220 to the center through total internal reflection inside the light guide plate 220, and uniform surface light may be emitted throughout the light guide plate by a pattern located on the front or rear surface of the light guide plate 220.

In the disclosed edge type backlight unit 200, a plurality of light sources 211 are provided on a support 280 that supports the light source, and the support 280 may fix the plurality of light sources 211 so that the positions of the plurality of light sources 211 are not changed.

The support 280 may be disposed on the side of the light guide plate 220 together with the plurality of light sources 211. For example, as shown in FIG. 14, the support 280 may be disposed on the left and right sides of the light guide plate 220. However, the arrangement of the support 280 is not limited to that shown in FIG. 14, the support 280 may be disposed on the upper and lower sides of the light guide plate 220, or may be disposed only on either the left side or the right side of the light guide plate 220.

The support 280 may be composed of a synthetic resin including a conductive power supply line for supplying power to the plurality of light sources 211 or may be composed of a printed circuit board (PCB).

Since the edge type backlight unit serves to diffuse light from the light guide plate 220, unlike FIGS. 12 and 13, the light diffusion sheet 270 may be omitted.

Light source 210 included in FIGS. 12 to 14 emits light of different peak center wavelengths from one light source 211, and is mixed into blue, green, and red white light while passing through the converter 230. White light with improved brightness and shift of a center wavelength through the optical sheet 250 is transmitted to the liquid crystal panel 110.

Through this, the disclosed display apparatus 100 can expand a color gamut compared to a conventional white LED, and can be applied to BT2020, which requires an extended gamut.

In addition, the disclosed display apparatus 100 may simultaneously have the same color absorption efficiency increase as compared to a conventional white LED, and thus may be applicable to high luminance and HDR.

1. A display apparatus comprising:
a light source configured to emit signal light having a first peak center wavelength and excitation light having a second peak center wavelength shorter than the first peak center wavelength; and
a converter configured to convert color of the excitation light emitted by the light source,
wherein the light source is configured to include at least one single chip in which a first semiconductor layer emitting the excitation light and a second semiconductor layer emitting the signal light are arranged in a horizontal or vertical direction.

2. The display apparatus of claim 1, wherein the first semiconductor layer is configured to stack an N-type semiconductor and a P-type semiconductor sequentially, and emit the excitation light.

3. The display apparatus of claim 1, wherein the second semiconductor layer is configured to stack an N-type semiconductor and a P-type semiconductor sequentially on the first semiconductor layer, and emit blue light or green light as the signal light.

4. The display apparatus of claim 1, wherein the first semiconductor layer and the second semiconductor layer are combined with Indium Tin Oxide (ITO) junction.

5. The display apparatus of claim 1, wherein the converter is made of photoluminescence (PL) material that absorbs the excitation light and converts color.

6. The display apparatus of claim 2, wherein the converter is configured to include at least one or more first electrodes and second electrodes spaced apart from each other, and
wherein the first electrode is formed to be connected to the P-type semiconductor on the first semiconductor, and the second electrode is formed to be connected to the N-type semiconductor on the second semiconductor.

7. The display apparatus of claim 1, wherein the light source includes a reflection layer provided under the first semiconductor layer and reflecting the excitation light and the signal light.

8. The display apparatus of claim 1 further comprising:
further comprising:
an optical sheet configured to improve brightness of the signal light emitted from the light source, and
wherein the optical sheet is configured to include a thin film element made of at least one of a dye and a pigment absorbing a preset wavelength band.

9. The display apparatus of claim 1 further comprising:
a light guide plate configured to distribute uniformly the excitation light and the signal light emitted by the light source; and
wherein the light source is provided on side of the light guide plate.

10. The display apparatus of claim 1 further comprising:
a light diffusion sheet configured to diffuse light passing through the light guide plate; and
wherein the light source is arranged on a light guide plate at predetermined intervals.

11. The display apparatus according to claim 1, wherein the converter is configured to convert the excitation light into at least one of green light and red light.

12. A method of manufacturing a display apparatus comprising a light source for emitting light and a converter for color conversion of excitation light emitted by the light source, comprising:
sequentially stacking a first semiconductor layer emitting the excitation light having a second peak center wavelength shorter than a first peak center wavelength and a second semiconductor layer emitting signal light having the first peak center wavelength; and
ITO bonding the first semiconductor layer and the second semiconductor layer.

13. The method of claim 12, wherein
the first semiconductor layer is configured to stack an N-type semiconductor and a P-type semiconductor sequentially, and
the second semiconductor layer is configured to stack an N-type semiconductor and a P-type semiconductor sequentially on the first semiconductor layer.

14. The method of claim 13 further comprising:
etching one side of the N-type semiconductor included in the first semiconductor layer.

15. The method of claim 14, wherein the etching includes etching the other side surface of the P-type semiconductor included in the first semiconductor layer and the P-type semiconductor of the second semiconductor layer, and
wherein the etching further comprising:
plating the etched portion; and
forming at least one first electrode and a second electrode that are spaced apart from each other.
